(19) United States
(12) Patent Application Publication
(10) Pub. No.: US 2024/0353188 A1
(43) Pub. Date: Oct. 24, 2024

(54) SYSTEMS AND METHODS FOR PRESSURE-BASED COOLING

(71) Applicant: Karthik B. Reddy, Bangalore (IN)

(72) Inventor: Karthik B. Reddy, Bangalore (IN)

(21) Appl. No.: 18/758,902

(22) Filed: Jun. 28, 2024

Related U.S. Application Data
(63) Continuation of application No. PCT/IN2022/051120, filed on Dec. 23, 2022.

(30) Foreign Application Priority Data
Dec. 28, 2021 (IN) 202141061134

(51) Int. Cl. F28F 13/00

(52) U.S. Cl. CPC F28F 13/00; F28F 2250/08

(57) ABSTRACT

A system for pressure-based cooling, said system comprising: a primary chamber (PC) comprising a base fluid (BF) in liquid state; a secondary chamber (SC) comprising a carrier fluid (CF), said secondary chamber (SC) configured to receive a controlled amount of said base fluid (BF), from said primary chamber (PC), said secondary chamber (SC) having a substantially lower pressure than said primary chamber (PC), said pressure differential causing said base fluid (BF) to change state from said liquid state to vapour state, at a saturation phase-threshold pressure, while it moves from said primary chamber (PC) to said secondary chamber (SC), absorbing heat from its surroundings—thereby, causing cooling at a first level, said carrier fluid (CF) aiding movement of said base fluid (BF); and a flow control interface (FCI) configured to control flow of said base fluid (BF) from said primary chamber (PC) to said secondary chamber (SC).

### RELATED APPLICATIONS

This application claims priority under 35 U.S.C. § 120 to, and is a continuation of, co-pending International Application PCT/IN2022/051120, filed Dec. 23, 2022 and designating the US, which claims priority to IN Application 202141061134, filed Dec. 28, 2021, such IN Application also being claimed priority to under 35 U.S.C. § 119. These IN and International applications are incorporated by reference herein in their entireties.

### FIELD

This invention relates to the field of cooling systems. Particularly, this invention relates to systems and methods for vacuum-based cooling.

### BACKGROUND

There is a general need to remove ‘unwanted’ heat from a system or an environment.

Conventional prior art cooling methods and systems, that cool a targeted system, typically, use a coolant that is circulated around a cooling system. Such methods, and systems, are plagued with the following problems:
1) Limited capacity per unit size, volume, and flow rate;
2) Non-linear cooling performance in the targeted system-a target that is closest to an inlet of coolant has most cooling effect, and a target that is closest to an exit of coolant has least cooling effect; as the coolant absorbs heat from the target and its temperature keeps increasing as it goes through the cooling system;
3) Difficulty in maintaining absolute target temperatures due to system dynamics;
4) Time to achieve target temperature is higher.

One other type of prior art cooling system depends on phase change of a liquid to absorb heat from its surroundings and thereby cooling the target. They are lacking in two aspects:
1) Non-direct cooling of target;
2) Inability to maintain target temperatures, when the ambient is lower than target temperature.

Electric Vehicles have been, progressively, finding increased market acceptance in recent years, and Electric Vehicles are predicted to be the norm in coming years, with today's conventional internal-combustion engine vehicles being phased out.

There have been many developmental breakthroughs in this field of Electric Vehicles and its infrastructure; where past limitations such as battery capacity, range, comfort, safety, and the like are no longer a deterrent. However, an aspect of ‘range anxiety’ still remains, unlike a traditional internal-combustion engine where it can be conveniently fueled up at fuel stations in few minutes, an Electric Vehicle still needs considerably higher charge times.

In order to solve this problem, technology has moved towards high-power charging, where a high charging current along with battery and electronics that support this high current charging are used. However, they all face an issue related to heating. Typically, heat is generated in any activity that involves energy/power, such as voltage conversion from grid, conditioning of voltage and current, charging of batteries, running of motors and peripherals, etc. Optimal control of operating temperatures greatly enhances the life, endurance, reliability, safety, etc. of these systems

Heat is a common problem with Electric Vehicles and its infrastructure; higher heat tends to reduce life, endurance, safety threshold and charge capacity of the battery and related systems. The higher the rate of charging, the higher are thermal loads and stresses, and, therefore, have consequential effect on batteries and its related systems.

In order to achieve acceptance of Electric Vehicles, a reliable, efficient, and quick-handling thermal management system is required. It is to be noted these thermal loads occur across an entire chain i.e. chargers (at a charging station, that is connected to a power grid), cables, charging controllers, and batteries on the Electric Vehicle.

To dissipate such heat, and improve the chain's working, active cooling is required. ‘Cooling’ is a process of removing heat from a low-temperature reservoir and transferring it to a high-temperature reservoir. The work of heat transfer is traditionally driven by mechanical means, but can also be driven by heat, magnetism, electricity, laser, or other means.

Evaporative cooling is a type of cooling which works on the principle of liquid evaporation by absorbing heat from its surroundings. During the evaporative cooling process, the liquid converts to its gaseous form

Heat Exchangers are, sometimes, used in active cooling. A ‘heat exchanger’ is a device that transfers heat from a fluid (liquid or gas) to pass to a second fluid without the two fluids mixing or coming into direct contact. Heat exchangers are commonly used in liquid cooling systems to dissipate heat from a fluid that has passed over a cold plate attached to the heat-producing component. The cool fluid is pumped through the system and back across the cold plate.

Traditionally, for the purposes of cooling, a cooling mechanism, such as ‘cooling towers’, was used to cool a coolant, and this coolant was circulated across targets that needed cooling. These prior art systems have inherent limitations which are as follows:
1. Specific heat absorption: Water or water-based coolants are normally used, and specific heat of water is about 4100 J/(KgK), i.e. 1 KG of water absorbs 4100 Joules of heat in order to increase its temperature by 1 deg C., thereby limiting the amount of heat that can be absorbed by a specific mass of system and time;
2. Lack of dynamic control of target temperature: time required to change target temperature of the coolant is high; due to the specific heat and volume of the coolant and distance from target to external exchanger;
3. Higher complexity: number of circuits required to implement the system is high;
4. Higher cost;
5. Higher time to achieve targeted temperature set-points.

According to one prior art citation, DKR20040038136, there is taught an aspect of evaporative cooling which uses evaporating a reservoir with water/coolant using lower pressure and using the reservoir as a heat exchanger to cool target. In this, vapour goes through a heat exchanger. However, there is a need to eliminate the water reservoir/coolant reservoir, and directly cool the target without specifically needing a heat exchanger.

According to another prior art citation, DUS4723415, there is taught an aspect of cooling which uses vacuum and spray of water in order to cool a container that is partially filled with water. The system, of this prior art, needs partial vacuum and partial water in an enclosure; partial vacuum aids in evaporation of a spray of water, which reduces temperature of water inside the said reservoir. However, there is a need to eliminate the water reservoir/coolant reservoir. Also, there is a need for cooling of a target, directly, as against cooling a water quantity inside the reservoir that, in turn, cools a coolant.

According to another prior art citation, DUS5209078, there is taught an aspect of cooling which uses vacuum to cool a chamber, that has water, and in turn a heat exchanger mechanism inside a vacuum chamber, that carries a cold coolant, to another heat exchanger outside. Here, an air cooler system for use with an air circulation system. According to this prior art, its heat exchanger/radiator in vacuum chamber is partially immersed in fluid. However, there is a need to eliminate such immersion in any fluid. Also, there is a need for cooling of a target, directly.

According to another prior art citation, WO2020248003A1, there is taught an aspect of cooling wherein a vacuum chamber, utilizes two fluids, that circulate the system in separate cycles. In this prior art system, one fluid is more volatile than the other. However, there is a need for a system which provides latent heat of evaporation-based cooling without needing two specific fluids with the specific volatility operating at different phases of system operation.

US Patent Publication number 20220203857 relies on a controller that alters a pressure of the coolant within the charge cable to maintain nucleate boiling of the coolant. Here, the citation teaches use of a single chamber of coolant, where the coolant absorbs the heat from the surroundings, and is particularly configured to be in nucleate state. Here, tiny vapour bubbles are formed, and break after they travel a bit in the distance. This citation teaches adjusting nucleate state by pressure, but that is within the same chamber, the heat absorbed by the evaporating fluid, at the surface of a hot body, is dissipated shortly after the vapour bubbles burst, into the coolant itself. The overall limit of heat extraction out of the system is still governed by the mass of coolant flow through the system, just as with a conventional coolant system, but the efficiency of heat transfer from the hot object into the coolant is higher than conventional coolant systems. In this prior art, the phase change (to nucleate state) of the coolant is only to transfer heat from a hot object into the coolant itself; and is not a complete phase change extraction (which is much more effective). In this prior art, heat is carried out by the liquid coolant in the system, and capacity is governed by mass of coolant flow, and accepted temperature differential between inlet and exit. Other limitation such as constant cooling temperature across the entire system in all cooling configurations and intensity still exist in this prior art system.

### SUMMARY

There is a need to address limitations of the prior art.

An object of the invention is to eliminate a water reservoir/coolant reservoir; for purposes of cooling.

Another object of the invention is to provide a system for cooling of a target, directly, as against cooling a second interface, such as water/fluid quantity inside the reservoir, that, in turn, cools a coolant/heat exchanger.

Yet another object of the invention is to eliminate immersion in any fluid.

Still another object of the invention is to cooling a target, directly.

An additional object of the invention is to provide a system which provides latent heat of evaporation-based cooling.

According to this invention, there are disclosed systems and methods for pressure-based cooling, said system comprising:
a primary chamber comprising a base fluid in liquid state;
a secondary chamber comprising a carrier fluid, said secondary chamber configured to receive a controlled amount of said base fluid, from said primary chamber, said secondary chamber having a substantially lower pressure than said primary chamber, said pressure differential causing said base fluid to change state from said liquid state to vapour state, at a saturation phase-threshold pressure, while it moves from said primary chamber to said secondary chamber, absorbing heat from its surroundings—thereby, causing cooling at a first level, said carrier fluid aiding movement of said base fluid; and
a flow control interface configured to control flow of said base fluid from said primary chamber to said secondary chamber.

In at least an embodiment, said base fluid, in said primary chamber, being a circulating type base fluid, caused by a pump, or a non-circulating type base fluid.

In at least an embodiment, said primary chamber being a thermally conductive primary chamber.

In at least an embodiment, said secondary chamber being lined with at least a fluid-absorbing thermally-conductive material to absorb said base fluid while it evaporates.

In at least an embodiment, said system comprising a target to be cooled, said target being selected from a group consisting of an outer surface of said secondary chamber, a surface of said primary chamber on a side of said secondary chamber, and a combination of both.

In at least an embodiment, said secondary chamber being connected to a mechanism that applies a pressure differential between said primary chamber and said secondary chamber, the amount of differential pressure is decided based on required cooling temperature and cooling intensity.

In at least an embodiment, said secondary chamber being a negative pressure (vacuum) chamber so as to lower boiling point of said base fluid entering said secondary chamber causing said base fluid to changes state from liquid state to vapour state by absorbing heat from its surroundings—thereby, causing cooling.

In at least an embodiment, a target being coupled to said primary chamber, in that, said base fluid absorbs heat from said target, from said primary chamber, whereas base fluid in said secondary chamber, directly absorbs heat of said base fluid in said primary chamber, which in-turn absorbs heat from said target.

In at least an embodiment, a target being coupled to said secondary chamber, in that, said base fluid absorbs heat directly from said target, from said secondary chamber, where purpose of said base fluid, in said primary chamber, is to supply said base fluid which evaporates in said secondary chamber to absorb heat from said target.

In at least an embodiment, said flow control interface being a barrier between said primary chamber and said secondary chamber, that allows a controlled amount of said base fluid into said secondary chamber, and onto said flow control interface.

In at least an embodiment, said flow control interface being a membrane, that allows said base fluid to flow through it, on application of at least one of the following:
pressure differential between said primary chamber and said secondary chamber;
mechanical force;
electronic signal;
resonant frequency.

In at least an embodiment, said flow control interface being integrated with mechanical or electromechanical micro valves, that allow flow of said base fluid from said primary chamber to said secondary chamber, said valves being actuated by:
pressure differential between said primary chamber and said secondary chamber;
mechanical force;
electronic signal;
resonant frequency.

In at least an embodiment, said primary chamber, said secondary chamber, and said flow control interface, all, being thermally conductive and flexible, in that, a semi-permeable membrane separates said primary chamber from said secondary chamber, said semi-permeable membrane being in fluid communication with said primary chamber and said secondary chamber.

In at least an embodiment, said secondary chamber being connected to a vacuum generator to generate vacuum in said secondary chamber, in that, said carrier fluid configured to carry vapors to said vacuum generator, and to maintain flow velocity that also aids cooling by vaporization of said base fluid on said flow control interface.

In at least an embodiment, said the flow control interface comprising valves configured to spray said base fluid from said primary chamber to said secondary chamber, thereby causing cooling at a second level.

In at least an embodiment, said primary chamber ensconcing said secondary chamber, concentrically, and co-axially, said flow control interface being valves on an inner circumference of said primary chamber, in that, one or more cables being configured to be passed through said secondary chamber such that said secondary chamber ensconce said one or more cables.

In at least an embodiment, said flow control interface comprising one or more flow-control valves for controlling said flow of said base fluid based on one or more parameters selected from a group of parameters consisting of: (a) required vacuum, (b) required temperature, (c) required flow rate, (d) required humidity, and/or (e) required atomization.

In at least an embodiment, said flow control interface comprising one or more flow-control valves for controlling said flow of said carrier fluid based on one or more parameters selected from a group of parameters consisting of: (a) required vacuum, (b) required temperature, (c) required flow rate, (d) required humidity, and/or (e) required atomization.

In at least an embodiment, said system comprising a control system conFIG. to control said primary chamber, said secondary chamber, and said flow control interface, in that, said control system being configured to:
control inlet valves of said base fluid and said carrier fluid;
control suction pressure of a mechanism that applies a pressure differential between said primary chamber and said secondary chamber;
control flow rate of a mechanism that applies a pressure differential between said primary chamber and said secondary chamber;
control temperature of said base fluid;
control temperature of said carrier fluid; and
control vacuum generation pressure in said secondary chamber.

In at least an embodiment, said system comprising a target to be cooled, said target being selected from a group consisting of an outer surface of said secondary chamber, a surface of said primary chamber on a side of said secondary chamber, and a combination of both, in that, said target being connected to a heat exchanger.

### BRIEF DESCRIPTION OF THE ACCOMPANYING DRAWINGS

FIG. 1 illustrates a schematic block diagram of one type of prior art's cooling system;

FIG. 2 illustrates a schematic block diagram of another type of prior art's cooling system;

FIG. 3 illustrates a prior art's liquid-cooled charging cable for vehicle charging; and

FIG. 4 illustrates a prior art's liquid-cooled battery pack system.

FIG. 5A illustrates a view of the invention's system in accordance with its aforementioned first embodiment;

FIG. 5B illustrates a cross-section of the invention's system in accordance with its aforementioned first embodiment;

FIG. 5C illustrates a cross-sectional working of the invention's system in accordance with its aforementioned first embodiment;

FIG. 5D illustrates an exemplary embodiment of shape-independent cooling systems of the invention's system in accordance with its aforementioned first embodiment;

FIG. 5E illustrates an exemplary embodiment showing a cross-section of an electric vehicle's charging cable with an integrated cooling system incorporating the invention's system in accordance with its aforementioned first embodiment;

FIG. 5F illustrates a cross-section view of the invention's system in accordance with its second embodiment;

FIG. 5G illustrates a cross-section view of the invention's system in accordance with its second embodiment, in which the secondary chamber is at saturation phase-threshold pressure and its control valve is active;

FIG. 5H illustrates an exemplary embodiment of a concentric cooling mechanism of the invention's system in accordance with its aforementioned second embodiment;

FIG. 5I illustrate s a cross-section view of the exemplary embodiment of a concentric cooling mechanism of the invention's system of FIG. 3B.3;

FIG. 6A illustrates a schematic block diagram of the current invention's cooling system;

FIG. 6B illustrates another schematic block diagram of the current invention's cooling system;

FIGS. 7A and 7B illustrate a cross-section of one such cooling cable assembly using this system and method;

FIG. 8 illustrates the system of FIG. 3 improved by this invention's phase-change charging cable;

FIG. 9 illustrates the system of FIG. 4 improved by this invention's phase-change system;

FIG. 10 illustrates an exemplary embodiment of a complete battery pack;

FIG. 11 illustrates an exemplary embodiment, of a cooling system architecture with sealed/recirculating carrier fluid circuit which is a gas in all operating conditions;

FIG. 12 illustrates an exemplary embodiment's graph which shows vacuum modulation to maintain target temperature; both, as a function of time;

FIG. 13A illustrates a battery pack for an electric vehicle with batteries; and

FIG. 13B illustrates a graph showing temperature across a battery pack, where ambient temperature is lower than required optimal temperatures.

### DETAILED DESCRIPTION

For the purposes of this specification, the following terms are defined:
‘Base Fluid’ (BF): A fluid, whose latent heat of vaporization, is used to absorb heat from a target, and whose natural state, in ambient temperature and pressure, is a liquid, and whose boiling point is reduced by reducing pressure to lesser than that of ambient pressure. Example: Water, Methanol

### Properties of the Base Fluid:

a) Liquid at ambient temperature and pressure;
b) Boiling point reduces to required target value by application of a vacuum pressure (negative pressure);
c) Heat of vaporization within acceptable limits that aids in meaningful extraction/absorption of heat from the target. Example, latent heat of vaporization of water is approximately 2200 KJ/Kg.
‘Carrier Fluid’ (CF): A fluid that aids movement of the Base Fluid. It is not a fixed fluid, but can be altered based on use case/s.
   Example: air, CO₂

### Properties of Carrier Fluid:

a) Works as a catalyst, to aid/assist primary function of cooling using base fluid;
b) Used to maintain flow, pressure, humidity, rate of response, temperature, and the like in a cooling chamber;
c) Aids in dispersion/movement and reducing heat of primary fluid through the cooling chamber, in liquid and gaseous form;
d) Aids in adjusting properties of base fluid; e.g. adding moisture to enhance elasticity of surface/s inside the cooling chamber.
‘phase-threshold pressure’: For a required target temperature, the pressure at which the liquid changes phase to vapour
‘Primary chamber’: A chamber which is used, by a base fluid in liquid state, in order to transport the fluid around a cooling circuit, to a target location, and function as a coolant depending on the construction and load demands of the system
‘Secondary chamber’: A chamber which is used by:
   (i) the base fluid while it converts from liquid to gaseous state, and
   (ii) the carrier fluid.

The secondary chamber is connected to a source that can generate a pressure differential, as well as a flow.
‘Flow control interface’: A medium that allows movement of the base fluid from the primary chamber to the secondary chamber. These can be mechanical valves, electro-mechanical micro valves, semi-permeable membranes, and the like; with a control/trigger being electrical signals, pressure differential, mechanical force, and the like.

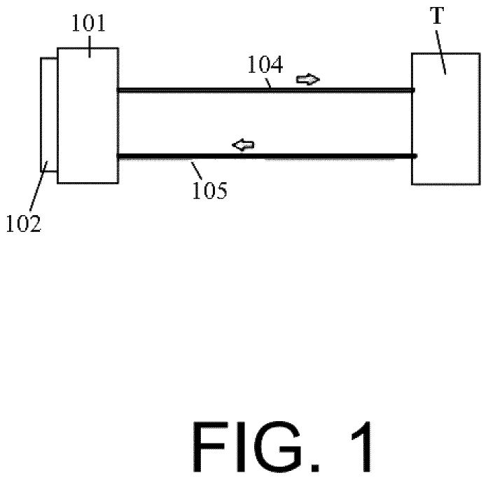

FIG. 1 illustrates a schematic block diagram of one type of prior art's cooling system.

According to FIG. 1, a cooling apparatus (101) is coupled to a heat exchanger (102) which may or may not be spaced apart from a target (T) that needs cooling. From the cooling apparatus (101), cold coolant (104) is sent to target (T) in order to cool the target (T). In turn, the coolant (103) becomes hot and hot coolant (105) is sent from target (T) back to cooling apparatus (101) to cool down.

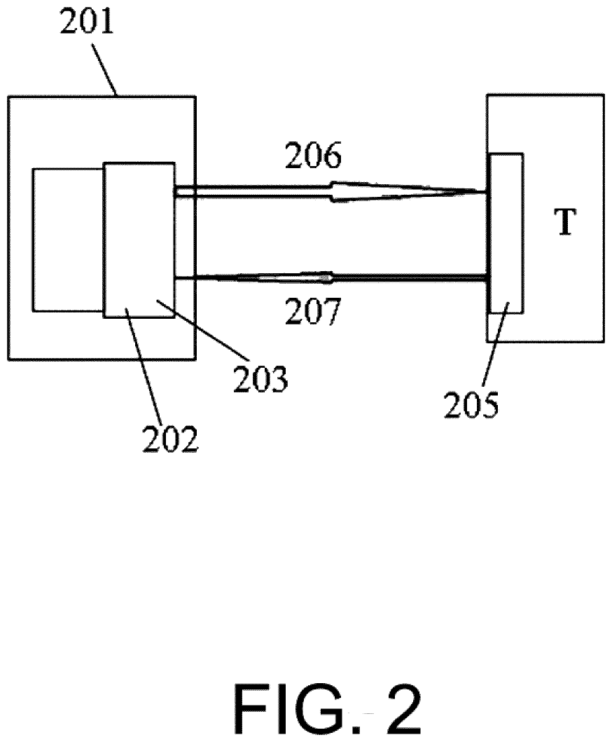

FIG. 2 illustrates a schematic block diagram of another type of prior art's cooling system.

According to FIG. 1, a cooling apparatus (201), with coolant (202), is coupled to a heat exchanger (203), on cooling apparatus (201) side, which may or may not be spaced apart from a target (T) that needs cooling, the target (T) also being coupled with a heat exchanger (205), on target (T) side. From the cooling apparatus (201), cold coolant (206) is sent to target (204) in order to cool the target (T). In turn, the coolant (206) becomes hot and hot coolant (207) is sent from target (T) back to cooling apparatus (201) to cool down.

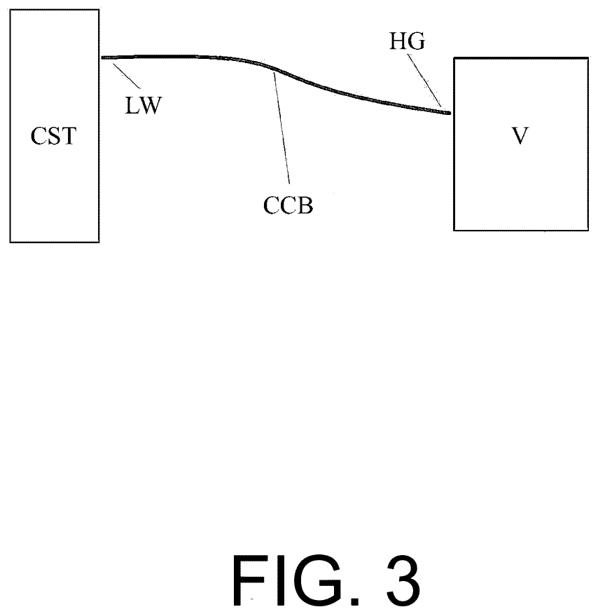

FIG. 3 illustrates a prior art's liquid-cooled charging cable for vehicle charging.

Here, a charging station (CST) charges a vehicle (V) by means of charging cable (CCB) which couples the charging station (CST) to the vehicle (V). Here, it was observed that, temperature was lowest (LW), on the charging station (CST) side on entry of fresh coolant to the charging station (CST). It was, further, observed that temperature was highest (HG), on the vehicle (V) side.

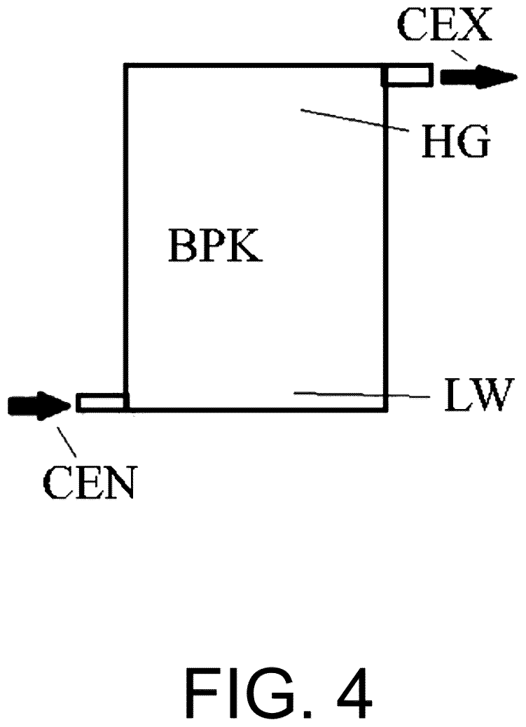

FIG. 4 illustrates a prior art's liquid-cooled battery pack system.

Here, a battery pack (BPK) receives cold coolant from an entry node (CEN) and exits the coolant, after cooling of the battery pack (BPK), from an exit node (CEX). Here, it was observed that temperature was lowest (LW), at the entry node (CEN). It was, further, observed that temperature was highest (HG), on the exit node (CEX) side.

According to this invention, there are disclosed systems and methods for pressure-based cooling.

Embodiments of this invention disclose a pressure-based, controlled phase-change, cooling system. The system and method, of this invention, has two functions:
i. a primary function is to cool a target (absorbing heat from target);
ii. a secondary function is to heat (thermally condition) the target to required temperatures.

According to exemplary embodiments, the target can be electronic components such as batteries, server systems, infrastructure coolers, control electronics, and the like.

The system can operate in three modes of cooling:
i. Target cooling from Primary chamber: Base fluid (BF) absorbs heat from a target (T), from primary chamber (PC), whereas the base fluid evaporation/boiling, in secondary chamber (SC), directly absorbs heat of the base fluid (BF) in the primary chamber (PC), which in-turn absorbs heat from the target (T);
ii. Target cooling from Secondary chamber: Base fluid (BF) absorbs heat directly from a target (T), from secondary chamber (SC), where purpose of the base fluid (BF), in primary chamber (PC), is to supply a coolant/base fluid (BF) which evaporates/boils in secondary chamber (SC) to absorb heat from the target (T);
iii. Combination of both the aforementioned methods.

In at least an embodiment, the system comprises at least one of each of a primary chamber (PC), a secondary chamber (SC), and a flow control interface (FCI). The base fluid (BF) is present in the primary chamber (PC) across a cooling circuit, and can be pumped through the cooling circuit. The secondary chamber (SC) has a controlled amount of base fluid (BF) allowed into it, via the flow control interface (FCI), and a negative pressure (vacuum) is applied in the secondary chamber (SC), which lowers boiling point of the base fluid (BF), causing it to boil/evaporate and absorb considerable heat from its surroundings (heat of evaporation). The flow control interface (FCI) can be implemented in many ways, but its primary function remains the same, i.e. to allow a controlled amount of base fluid (BF) from primary chamber (PC) to secondary chamber (SC). Heat absorption, at the secondary chamber (SC), can be utilized in multiple ways.

In at least an embodiment, the primary chamber (PC) is a module/unit/assembly which provides a path for the base fluid (BF). The primary chamber (PC), other than providing a path for the base fluid (BF), can itself function as a conventional heat absorbing system, without utilizing heat absorption by evaporation. The base fluid (BF), in the primary chamber (PC), can either be a circulating or non-circulating type. For systems where the base fluid (BF) also works a generic coolant in liquid form, a circulating type has an advantage of using an external heat exchanger to dissipate heat. A pump or similar apparatus can be used to circulate the base fluid (BF). For uses where the base fluid (BF) functions as a coolant, the enclosure of the primary chamber (PC) needs to be thermally conductive to absorb heat from the surroundings.

In some embodiments, the primary chamber (PC) can be circulating or non-circulating type.

In some embodiments, the primary chamber (PC) can be a thermally conductive type.

In at least an embodiment, the secondary chamber (SC) is a module/unit/assembly whose main purpose is to allow application of a pressure differential, with respect to pressure in the primary chamber (PC), and to serve a path to carry vapours of the base fluid (BF) and carrier fluid (CF). It is important to highlight the fact that evaporated fluids, in vapour state, have an unrestricted path out of the system, which does not inhibit flow of the base fluid (BF) in the primary chamber (PC). The phase-threshold pressure is modulated such that the system operates in the conventional thermally efficient zone, without breaching the limitations of the critical heat flux, as the temperature differential between the target object and the required setpoint temperature can by dynamically adjusted to stay within efficient heat transfer ranges. It is in this chamber that the base fluid (BF) changes state from liquid to vapour, absorbing heat from the surroundings. The secondary chamber (SC) can be optimized to absorb heat depending on the application, the target could be an outer surface of the secondary chamber (SC), or a surface of the primary chamber (PC) on a side of the secondary chamber (SC), or a combination of both. The inner surface of the secondary chamber (SC) can be lined with at least a fluid-absorbing thermally-conductive material, which functions like a sponge to hold the base fluid (BF) while it evaporates (as evaporation is not instantaneous), and enhances efficiency of the system. This material:
absorbs base fluid (BF) that is discharged from the flow control interface (FCI);
conducts heat from surroundings to base fluid (BF) absorbed in itself which evaporates absorbing this heat;
functions as sponge/holder for discharged base fluid (BF) in order to prevent base fluid (BF), that is yet to be evaporated, from dripping or moving away from targeted (T) location.

In at least an embodiment, the secondary chamber (SC) is connected to a mechanism that applies a pressure differential between the primary chamber (PC) and secondary chamber (SC); the amount of differential pressure is decided based on required cooling temperature and cooling intensity. A carrier fluid (CF) is utilized in this chamber, which aids in movement of evaporated gaseous base fluid (BF), as well as aids in evaporation of base fluid (BF). Carrier fluid (CF) also functions as a means to enhance efficiency, life, and operational range of the system. For example, carrier fluid (CF) can have a mixture of a silicon-based lubricant, that restores/maintains flexibility and elasticity of the flow control interface (FCI).

In at least an embodiment, the flow control interface (FCI) is a module/unit/assembly which is the barrier between the primary chamber (PC) and the secondary chamber (SC), that allows a controlled amount of base fluid (BF) into the secondary chamber (SC), and onto itself i.e. the flow control interface (FCI). This barrier, at its simplest implementation, can be a membrane, that allows base fluid (BF) to flow through it, on application of:
a pressure differential between the primary chamber (PC) and the secondary chamber (SC);
a mechanical force, like a stretch, strain, compression, etc.

In some embodiment, the flow control interface (FCI) can be integrated with mechanical or electromechanical micro valves (V), that allow flow of base fluid (BF) from the primary chamber (PC) to the secondary chamber (SC). These valves (V) can be actuated by:
pressure differential between the primary chamber (PC) and the secondary chamber (SC);
electrical signal;
resonant frequency;
mechanical stress, pressure, stretch, etc.

Apart from being a medium to allow flow of base fluid (BF) from the primary chamber (PC) to the secondary chamber (SC), the flow control interface (FCI) can also function as a cooling/heat exchanger to the base fluid (BF) in primary chamber (PC). When the base fluid (BF) in the primary chamber (PC) is used as a generic coolant, where cooling of the target is also done by it, heat absorbed into the base fluid (BF), from target surroundings, can be extracted by the flow control interface (FCI) that has base fluid (BF) onto itself on a surface that is exposed to the secondary chamber (SC), where application of a pressure differential on the secondary chamber (SC), evaporates/vapourises the base fluid (BF) on the flow control interface (FCI) drawing heat from its surroundings (i.e. from the base fluid (BF) in primary chamber (PC)).

The arrangement of the primary chamber (PC), secondary chamber (SC), and flow control interface (FCI) are many. Some methods are described, in detail, below.

In at least a first embodiment, relating to arrangement of the primary chamber (PC), secondary chamber (SC), and flow control interface (FCI).

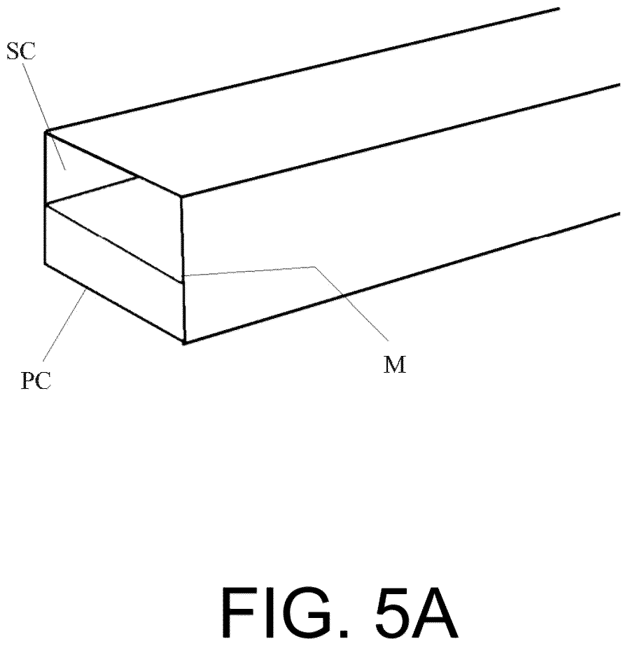

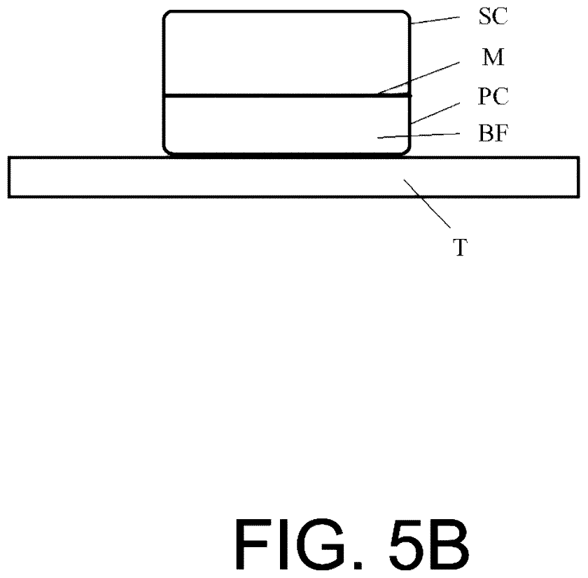

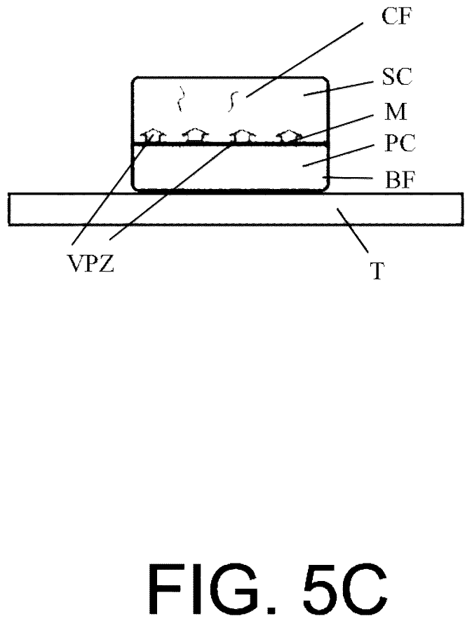

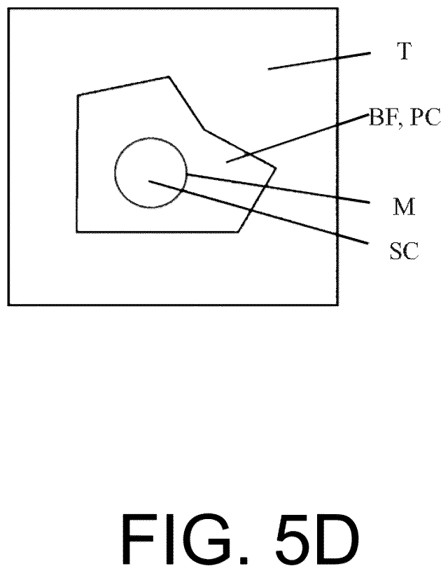

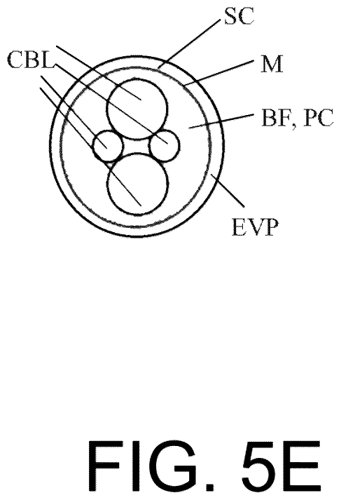

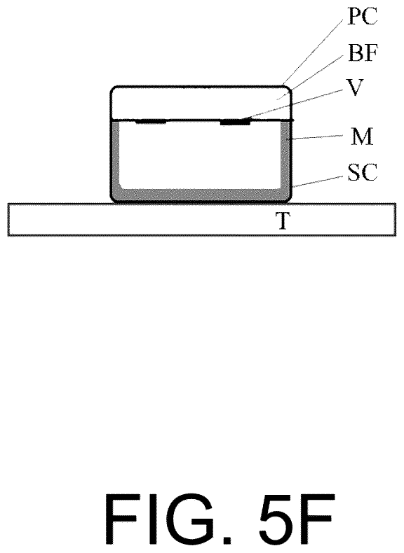

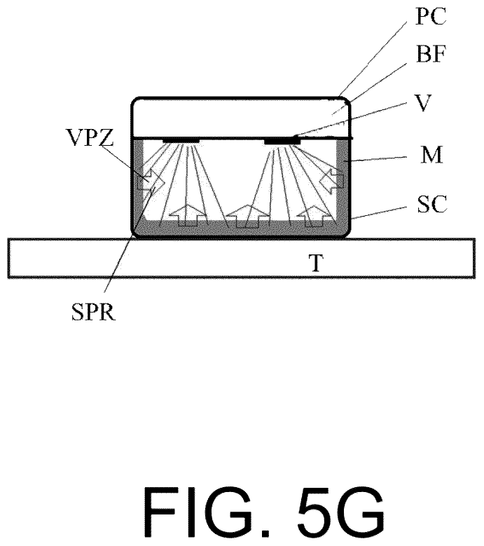

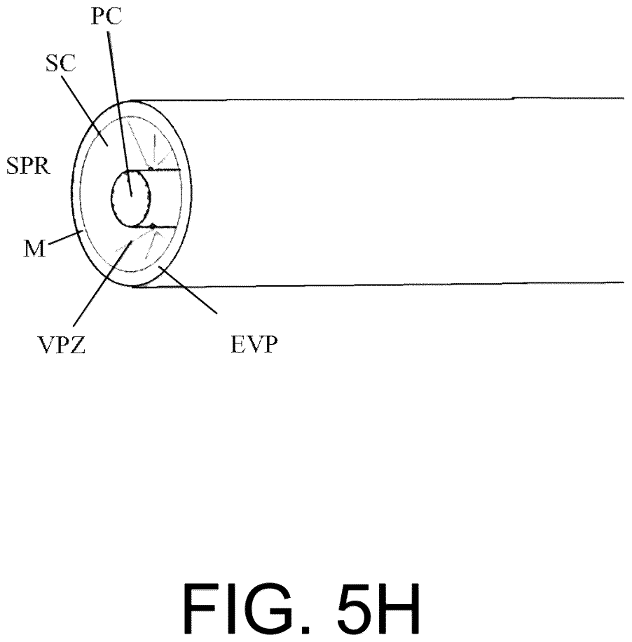

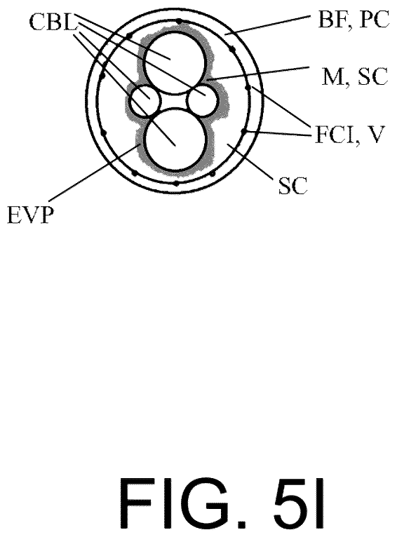

FIG. 5A illustrates a view of the invention's system in accordance with its aforementioned first embodiment.

FIG. 5B illustrates a cross-section of the invention's system in accordance with its aforementioned first embodiment.

FIG. 5C illustrates a cross-sectional working of the invention's system in accordance with its aforementioned first embodiment.

In at least this first embodiment, cooling system is made up of primary chamber (PC), secondary chamber (SC), and flow control interface (FCI), and the materials are all thermally conductive, they can also be flexible so that it can be routed across non-regular shapes and sizes for cooling target. Typically, a semi-permeable membrane (M) separates the primary chamber (PC) from the secondary chamber (SC).

In its simplest form, the coolant/base fluid (BF), itself, can be dynamically cooled, while absorbing heat from the target (T). Many current cooling applications use the coolant to cool the target (T), and with minimal upgrades/changes to existing infrastructure, this dynamically cooled method can be implemented.

When cooling requirement is low, or if linear cooling temperature is not required, the coolant/base fluid (BF) that is circulating through the cooling circuit might suffice, where only the primary chamber (PC) is used, while the flow control interface (FCI) and the secondary chamber (SC) remain in non-active mode. When cooling loads increase, pressure inside the secondary chamber (SC) is reduced towards a phase-threshold pressure, which forces the base fluid (BF) through the flow control interface (FCI) membrane (M) into the secondary chamber (SC), and the base fluid (BF) ‘soaks’ the flow control interface (FCI), and when pressure inside the secondary chamber (SC) reaches the phase-threshold pressure, the base fluid (BF) that is ‘soaking’ the flow control interface (FCI) boils, absorbs heat from its surroundings, primarily being the base fluid (BF) in primary chamber (PC).

Here, at phase-threshold pressure, in the secondary chamber (SC), the base fluid (BF) vapourizes (VPZ) from wet/damp membrane (M), that absorbs heat from the base fluid (BF) into the primary chamber (PC).

The flow control interface (FCI) membrane (M) can be chosen to suit cooling needs (permeability, thickness, and the like).

The carrier fluid (CF) is used to carry vapours to a vacuum generator, and to maintain flow velocity that also aids cooling by vapaourization of the base fluid (BF) on the flow control interface (FCI).

Here, carrier fluid (CF) aids in movement of vapours. The carrier fluid (CF) is used to carry the vapours to the vacuum generator, and to maintain flow velocity that also aids cooling by vapaourization of the base fluid (BF) on the flow control interface (FCI).

Summarily, evaporation of the base fluid (BF) from the flow control interface (FCI) cools the flow control interface (FCI) and, subsequently, the base fluid (BF) inside the secondary chamber (SC).

Therefore, dynamic cooling of the base fluid (BF)/coolant is achieved; and it is simpler to integrate into existing coolant-based cooling systems, high cooling capacity than using just coolant alone, same cooling target temperature across the system.

FIG. 5D illustrates an exemplary embodiment of shape-independent cooling systems of the invention's system in accordance with its aforementioned first embodiment.

FIG. 5E illustrates an exemplary embodiment showing a cross-section of an electric vehicle's charging cable with an integrated cooling system incorporating the invention's system in accordance with its aforementioned first embodiment.

Here, cables (CBL) carrying signals and high-power supply and ground are seen.

Here, base fluid (BF) from membrane (M) absorbs heat from surroundings while it evaporates (EVP) due to low pressure in secondary chamber (SC).

In at least a second embodiment, relating to arrangement of the primary chamber (PC), secondary chamber (SC), and flow control interface (FCI).

FIG. 5F illustrates a cross-section view of the invention's system in accordance with its second embodiment.

FIG. 5G illustrates a cross-section view of the invention's system in accordance with its second embodiment, in which the secondary chamber is at phase-threshold pressure and its control valve is active.

In at least this second embodiment, heat is directly absorbed from the target (T) to the secondary chamber (SC). The inner surface of the secondary chamber (SC) has ability to hold/absorb the base fluid (BF) that is sprayed from the primary chamber (PC) while in liquid state. The flow control interface (FCI) is made up of mechanical or electromechanical valves (V), that open in a controlled way, in order to allow the base fluid (BF) from the primary chamber (PC) to flow/spray into the secondary chamber (SC). These valves (V) can be activated by pressure, force, electronic signals, and the like (example, piezoelectric microvalve, pressure based micro valve, and the like).

The target heat is absorbed mainly by the secondary chamber (SC), in this second embodiment, and the primary chamber (PC), in this second embodiment, is merely used to transport the base fluid (BF) across the circuit.

The pressure in the secondary chamber (SC) is set to required value, and the flow control interface (FCI) valves (V) are activated which sprays the base fluid (BF) from the primary chamber (PC) to the secondary chamber (SC). The larger portion of the base fluid (BF) that is not immediately vapourized at the time of spray is deposited on the inner surface of the secondary chamber (SC) that ‘holds/absorbs’ the base fluid (BF) in liquid form, which vapourizes subsequently, absorbing heat from the surroundings.

Here, base fluid (BF) vapourizes (VPZ) from secondary chamber (SC), absorbing heat from surroundings.

Here, base fluid (BF) is sprayed (SPR) onto inner absorption layer of secondary chamber (SC).

Summarily, heat from the target (T) is absorbed by the base fluid (BF) that evaporates in the secondary chamber (SC) which is at phase-threshold pressure.

Therefore, there is achieved, using this second embodiment, high heat absorption, direct and immediate cooling, variable control, distributed multi-point cooling.

FIG. 5H illustrates an exemplary embodiment of a concentric cooling mechanism of the invention's system in accordance with its aforementioned second embodiment.

Here, base fluid spray (SPR) can be seen.

Here, evaporation (EVP) of base fluid (BF) from absorbent surface (M) of secondary chamber (SC), can be seen, absorbing surrounding heat.

Here, carrier fluid (CF) carries vapours of base fluid (BF).

FIG. 5I illustrate s a cross-section view of the exemplary embodiment of a concentric cooling mechanism of the invention's system of FIG. 5H.

Here, evaporation (EVP) of base fluid (BF) from secondary chamber (SC) cools the cable assembly (CBL).

In at least this second embodiment, cooling system is made up of primary chamber (PC), secondary chamber (SC), and flow control interface (FCI).

It is to be noted that the system, and method, of this invention, can work as a conventional thermal exchange mechanism (recirculating base fluid (BF)), or as high-performance cooling mechanism, within the same system (using electronically controlled valves).

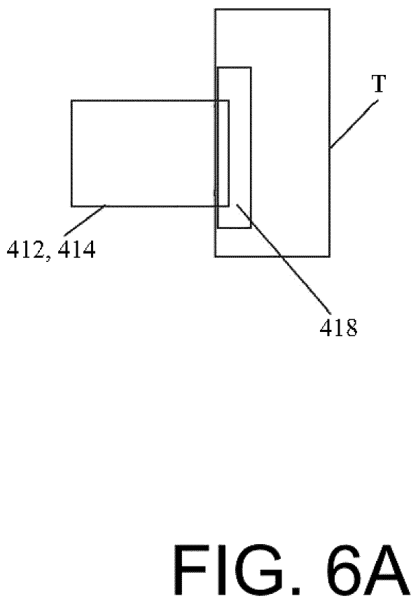

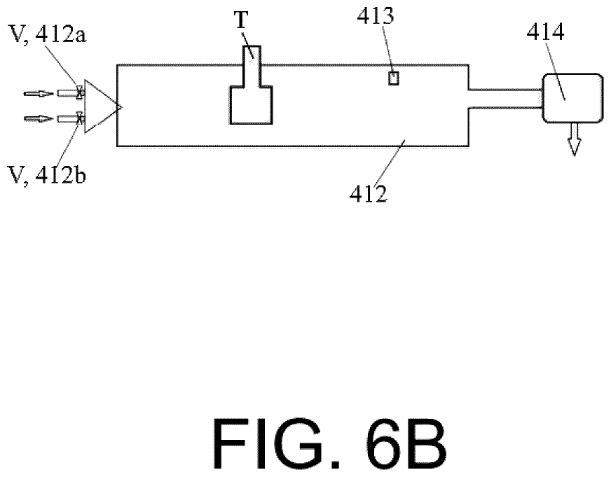

FIG. 6A illustrates a schematic block diagram of the current invention's cooling system.

FIG. 6B illustrates another schematic block diagram of the current invention's cooling system.

In at least an embodiment, of this invention, there is provided a cooling chamber (412, secondary chamber) which is a sealed unit. Typically, the cooling chamber comprises a first controller inlet (412a, flow control interface) for allowing controlled input of a base fluid (BF) which is stored in a base fluid storage chamber. Additionally, and optionally, the cooling chamber (412) comprises a second controller inlet (412b) for allowing controlled input of a carrier fluid (CF). Preferably, the carrier fluid (CF) aids in dispersion of the base fluid (BF).

In at least an embodiment, of this invention, there is provided a vacuum generating apparatus (414) which is coupled to an exit of the cooling chamber (412) in order to generate vacuum in the sealed cooling chamber (412). In some embodiments, the cooling chamber (412) has suitable accessibility to install sensors, draining mechanism, and the like. Sensors (413) inside the cooling chamber (412) monitor vital parameters such as temperature, pressure, humidity, and the like; and sensors, on the exit passage of vacuum pump, measures humidity, flow, and the like parameters which provide a real-time state estimation of constituents of the base fluid (BF) and the carrier fluid (CF) inside the cooling chamber, which are used by an overall control system.

In at least an embodiment, of this invention, there is provided a target (T), which is to be cooled, with a heat exchanger (418) coupled to the target (T). The target/target object (416), which needs to be cooled, is installed inside (or in communication with) the sealed cooling chamber (412). The target object (T), itself, can be a heat exchanger that furthers cools peripherals downstream, or a primary heat generating system such as batteries, electronic circuits, and the like.

In at least an embodiment, of this invention, the target (T) is provided in an enclosed chamber which is a low-pressure chamber. A control valve (V) is provided between the base fluid storage chamber and the low-pressure chamber. The base fluid (BF) is allowed to enter into the passage/cavity/enclosed space, to reach the low-pressure chamber where cooling function is required. Once the valve (V) is opened, the base fluid (BF) reaches the low-pressure chamber, it is sprayed into the low-pressure chamber due to pressure differential, and the target (T) which is to be cooled is also, simultaneously, sprayed upon. The base fluid (BF) boils/evaporates due to lower ambient pressure inside the low-pressure chamber (the base fluid (BF) such that to utilize this property), thereby drawing considerable amount of heat from the surface of the low-pressure chamber that it was sprayed on. Cooling is achieved by two factors:
1. Evaporation of base fluid (BF) that draws heat from target (primary) (T);
2. Spray of base fluid (BF) itself, where a portion of heat of the base fluid

(BF) is used and that portion of base fluid (BF) evaporates, cooling the rest of the base fluid (BF) that is still in liquid form.

The control valves (V) can be activated:
(a) electronically; and/or
(b) Mechanical force, stretch, compress, and/or
(c) by pressure differential between the base fluid (BF) chamber and low-pressure chamber.

In case of (a) electronically actuated valves, such as piezo valves, a controller turn the valve on and off.

In case of (b) mechanical force-based valves, an external force applied will open and shut the valves.

In case of (c) pressure actuated mechanical valves, the low-pressure pressure can be modulated to open and shut the valves, thereby controlling the amount and frequency of the base fluid (BF) being sprayed into the low-pressure chamber.

It is to be noted that each pressure actuated valve is configured per temperature range per pressure range. A network of valves can also be configured with one or more valves being defined per target.

The system can be configured to provide different target cooling temperatures and intensity across the whole system, without any additional systems.

In case of mechanical valves, the valve opening and flow characteristics can be sized to meet target temp and intensity of cooling, the whole system controlled by the adjustable low-pressure.

In case of electronically controlled valves, the flow of valves can be sized to match the intensity of cooling, and the switching cycle can be used to control the operating temperature and intensity

In case the system needs to circulate base fluid (BF), without needing to do a phase change, and transfer the heat from base fluid (BF) to target (T), or target (T) to base fluid (BF), that also can be achieved while using electronically controlled valves.

The flow/suction of vacuum generating apparatus (14), along with control/s, via control valves (V) of flow and quantity of base fluid (BF) (through first controller inlet 412a) and carrier fluid (CF) (through second controller inlet 412b), gives complete control of the cooling system characteristics.

In at least an embodiment, the first controller inlet (412a) is a flow-control valve (V) required for controlling flow of base fluid (BF) based on one or more parameters selected from a group of parameters consisting of: (a) required vacuum, (b) required temperature, (c) required flow rate, (d) required humidity, and/or (e) required atomization.

In at least an embodiment, the second controller inlet (412b) is a flow-control valve (V) required for controlling flow of carrier fluid (CF) based on one or more parameters selected from a group of parameters consisting of: (a) required vacuum, (b) required temperature, (c) required flow rate, (d) required humidity, and/or (e) required atomization.

The base fluid (BF) and carrier fluid (CF) are regulated into the cooling chamber (412), via respective valves (V) (412a, 412b), and the vacuum generating apparatus (414) reduces pressure inside the cooling chamber (412); thereby, creating a pressure differential, to a required value, between the external environment and the sealed cooling chamber (412). This required value is such that the boiling point of the base fluid (BF) reaches target cooling temperature, at which point, latent heat of vaporization of the base fluid (BF) is utilized to absorb heat from the target object (416); thereby, cooling it (this provides a first level of cooling). The carrier fluid (CF), that is in its gaseous form, even in its normal form in an external environment, undergoes cooling by adiabatic expansion while it moves from its ambient pressure to a lower pressure inside the cooling chamber (412); thereby, assisting in an overall cooling effect on the target object (416) (this provides a second level of cooling). The carrier fluid (CF) assists in atomization and dispersion of the base fluid (BF) spray onto the target (T) needing cooling, and also assists in evaporation of base fluid (BF) drawing heat from the system, which maximizes cooling effectiveness and efficiency.

Essentially,
the pressure change, caused by the vacuum generating apparatus (414) in the cooling chamber (412), with respect to ambient pressure, the base fluid (BF) changes its phase from liquid state to gas state; thereby, absorbing latent heat of evaporation and, thereby, cooling the target object (416);
the evaporating temperature, of the base fluid (BF), is controlled by application of vacuum pressure, through the vacuum generating apparatus (414); this allows dynamic change of target cooling temperature by adjusting the vacuum pressure;
the base fluid (BF) is carried to all required areas, and is allowed to be injected/sprayed onto the target (or near the target) (T) that needs cooling, by means of a hose or pipe, and gets sprayed into the secondary chamber (SC) via the flow control interface (FCI) valves;
the heated base fluid (BF) is used for purpose of heating the target (T) [e.g. when temperature of a target (such as an EV battery, or to enhance mobility of the flexible charging cable which could get hard in cold conditions) is lower than required (say −10 deg C.), like in cold countries, the battery (and any other peripherals than can benefit from it) can be primed to optimal temperature by circulating warm base fluid—in the same circuit, the warm base fluid brings the batteries to optimal temperature and primes them up for charging, while the base fluid in other parts of the circuit continue to work to cool the targets (such as charging cable, PCBs, power modules, etc.), thus allowing warming and cooling functions within the same architecture.

Thus, the system and method of this invention provides a pressure-based (due to the vacuum generating apparatus (414)) phase-change setpoint control (of the base fluid (BF) and the carrier fluid (CF)) for cooling a target (T); thereby, providing absolute control in terms of cooling parameters.

In some embodiments, the valves (412a, 412b) are mechanical microvalves that are actuated by a differential pressure.

In some embodiments, the valves (412a, 412b) are piezoelectric electronic valves that are actuated by a differential pressure and that control the base fluid (BF), when in liquid state, to be sprayed on to a target.

In at least an embodiment, of this invention, there is provided a control system is provided to, efficiently, manage the whole system. The control system controls the inlet valves (412a, 412b) of the base fluid (BF) and the carrier fluid (CF). The control system also manages suction pressure and flow rate of the vacuum generating apparatus (418), at its barest minimum, with feedback from various sensors, of the system, and in accordance with a prediction algorithm.

In at least an embodiment, the whole system can be an open or closed circulating mechanism, in that, a mixture of the base fluid (BF) and the carrier fluid (CF), at the exit of the vacuum generating apparatus (414) can be recirculated back into inlet valves (412a, 412b), of the cooling chamber (412), after heat dissipation through a heat exchanger (418) or a mixture of the base fluid (BF) and the carrier fluid (CF) can be vented into the environment, and fresh fluids can be supplied to the inlet valves (412a, 412b).

The system and method of this invention provide a two-stage cooling:
a) at the time of spray/atomization, absorbs ambient heat;
b) at time of phase change, that is brought about by change in pressure.

Here, the following principles are used for cooling:
1) primary base fluid (BF) evaporating (latent heat of evaporation) due to low pressure;
2) primary base fluid (BF) evaporating due to evaporation induced by the effect of the flow with/of the carrier fluid (CF) (e.g. blowing air on to a moist hand cools the hand);
3) a carrier fluid (CF) aided atomized layer of base fluid (BF) deposited on target to be cooled, that enhances the efficiency of point no. mentioned above.

Movement, through the flow control interface (FCI) can be in many ways:
in case of membrane, it ‘seeps’ through, mechanical/electromechanical valves which can be configured to have fluid movement in a certain pattern and consistency [e.g. tiny opening/s, with multiple holes, would get them more atomized, etc].

Because the base fluid valve (412a) and the carrier fluid valve (412b) are regulated, as required, by a control system, it allows a fine stream of water/primary fluid to spray from the valve onto the target (T) that needs cooling. The carrier fluid (CF) aids in movement of the base fluid (BF), as well as cools the base fluid (BF) by aiding in vaporization of the fine spray of base fluid (BF) that induces a cooling effect on the rest of the base fluid (BF).

Lower pressure in the cooling chamber (412) reduces boiling point of the spray of primary fluid onto the target (T), which boils the base fluid (BF) while absorbing the heat from target (T).

Additionally, when a non-harmful base fluid (BF) is used, it can be vented to environment. In other cases, a closed loop of an exit of mixture of the base fluid (BF) and the carrier fluid (CF) can be directed through the heat exchanger (418) and then routed back into the base inlet valve (412a) and carrier inlet valve (412b).

According to a non-limiting exemplary embodiment, the aforementioned system and method can be manifested into a form a cooling cable that can be used in conjunction with electronics (target) that need cooling.

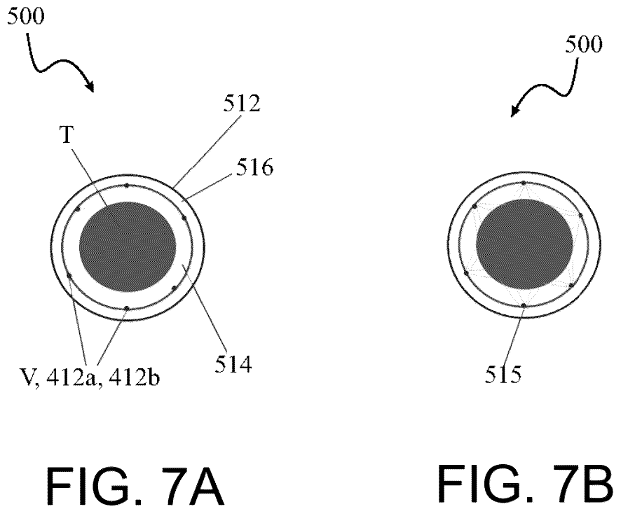

FIGS. 7A and 7B illustrate a cross-section of one such cooling cable assembly (500) using this system and method.

In preferred embodiments,
the cable assembly comprises a ‘carrier forward path’ that runs across all the areas that need cooling;
the cable assembly comprises a ‘vacuum return path’ in which vacuum is applied and is also a return path for the base fluid (BF) that has changed its state and, thereby, absorbs heat.

FIGS. 7A and 7B illustrate a coil (416), being the target, that needs cooling. An outer body (512) is co-axial to the coil (416). The coil is ensconced, co-axially, by a first chamber (514) which is further ensconced, co-axially, by a second chamber (516) which is further ensconced, co-axially, by the outer body (512). Reference numeral 515 refers to spray of mist. The outer body (512) is a flexible sheath which renders flexibility to the cooling cable assembly.

In at least an embodiment, of the cooling cable assembly (500), there are provided two paths:
carrier forward path (or inlet);
vacuum return path (or outlet).

The cooling cable assembly (500) comprises pressure dependent valves (412a, 412b), that open a passage depending on the pressure differential. These valves could be mechanical valves or electronically controlled piezoelectric valves or temperature-dependent valves.

Cooling is achieved in two stages:
while the base fluid (BF) is sprayed;
while the base fluid (BF) changes state due to change in latent heat of evaporation due to application of a vacuum.

The valves ensure that there is controlled amount of base fluid (BF). This provides the following advantages:
when the base fluid (BF) evaporates, volume of the resultant gas is many times higher—which places additional high dynamic loads on the vacuum generating apparatus (414)—however, using a controlled amount of demand-based quantity reduces the load and increases efficiency;
direct cooling: no wastage of efficiency and time to cool, as compared to having to use an intermediate heat exchanger, or a large amount of liquid in which there is excessive volume of evaporated fluid;
dynamically adjustable target temperatures and cooling intensity;
measurable volume of fluid used, that aids in computation of control electronics;
Inherent safety: In case of leaks, there is no possibility of an explosion like in the case of normally refrigerated systems, as this is vacuum based, whatever ruptures or leaks will always be under a negative pressure;
specific location-based cooling intensity: in case of mechanical valves that use a pressure differential to open, a lower differential valve can be used in places that have high heat generation, and mechanical valves with higher pressure differential can be used in other places;
Specific location-based cooling intensity: in case of electronically controlled valves, the adjustment is computer/electronic controlled.

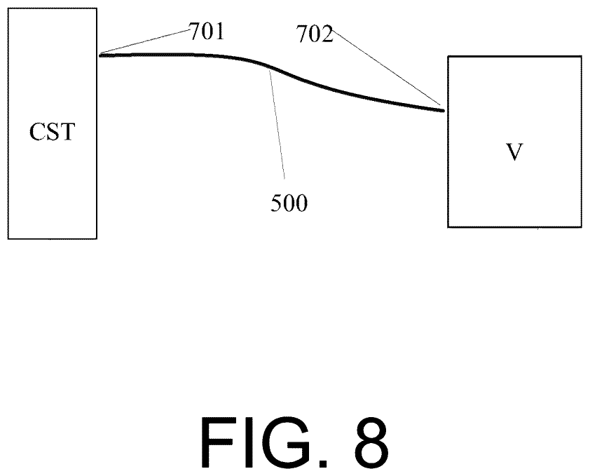

FIG. 8 illustrates the system of FIG. 3 improved by this invention's phase-change charging cable (500).

Here, the charging station (CST) charges the vehicle (V) by means of this invention's charging cable (500) which couples the charging station (CST) to the vehicle (V). Here, it was observed that the temperature across the system (701, 702), i.e. on the charging station (CST) side and on the vehicle (V) side, remained the same.

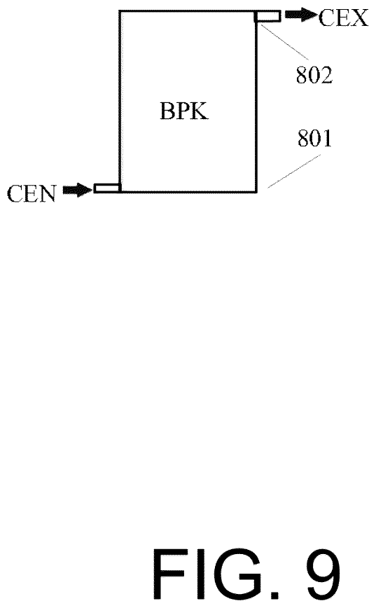

FIG. 9 illustrates the system of FIG. 4 improved by this invention's phase-change system.

Here, the battery pack (BPK) uses this invention's system for cooling. Here, it was observed that the temperature across the system (801, 802) remained the same.

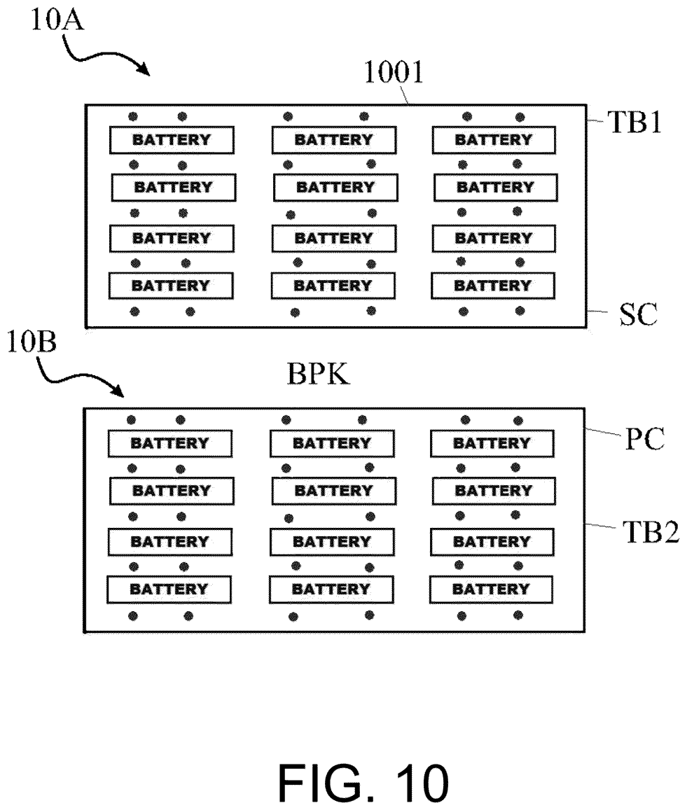

FIG. 10 illustrates an exemplary embodiment of a complete battery pack (BPK).

Here, reference numeral 1001 refers to thermally conductive liquid absorbing material.

In at least an embodiment (10A), an inner side of a first set of tubes (TB1) is a primary chamber (PC) and its outer side is a flow control interface (FCI). Here, heat absorbing takes place from target from secondary chamber (SC).

In at least another embodiment (10B), an inner side of a second set of tubes (TB1) is a secondary chamber (PC) and its outer side is a flow control interface (FCI). Here, heat absorbing takes place from target from primary chamber (PC).

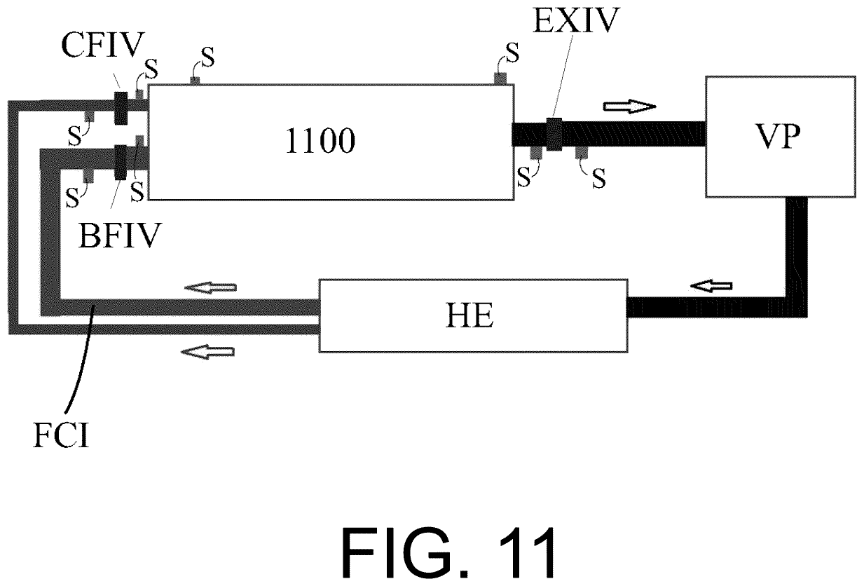

FIG. 11 illustrates an exemplary embodiment, of a cooling system architecture with sealed/recirculating carrier fluid circuit which is a gas in all operating conditions.

Here, BFIV refers to base fluid inlet control valve.

Here, CFIV refers to carrier fluid inlet control valve.

Here, EXIV refers to exit control valve.

Here, 1100 refers to the system of this invention

Here, HE refers to heat exchanger.

Here, VP refers to vacuum pump.

Here, the squares(S) refer to various temperature and pressure sensors deployed throughout the system.

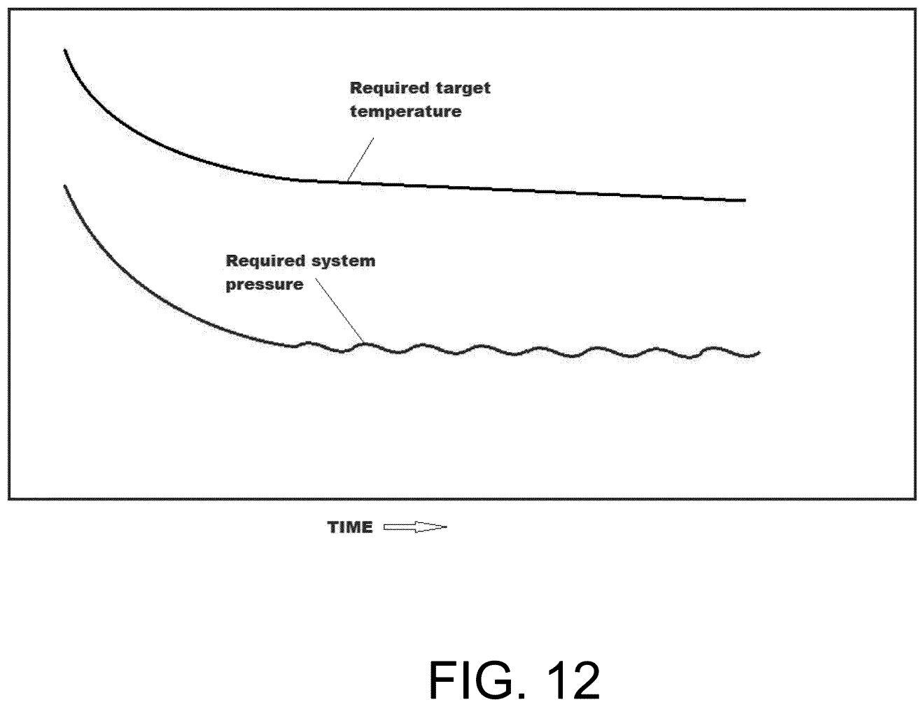

FIG. 12 illustrates an exemplary embodiment's graph which shows vacuum modulation to maintain target temperature; both, as a function of time.

By being able to monitor the inlet valve flow rate and exit valve flow rate, temperature and pressure, the controller can derive the amount of vapour generated, cooling demands, target temperatures, and control the pump pressure and the valves for base fluid and carrier fluid flow, flow control interface, etc. E.g. if cooling demand is low, exit vapour volume is lower, and, subsequently base inlet valve sand carrier inlet valves can lower flow, and the vacuum pump can lower the flow rate for the same target pressure.

In the above example, carrier fluid is air and is always a gas in operating conditions.

In the current invention, when compared with prior arts, the use of a dedicated chamber provides a significantly more advantage since a dedicated chamber is required to carry out the evaporated fluids; this enhances cooling capacity per unit volume of coolant-entire heat is discharged at an external heat exchanger, and aids in maintaining a regulated temperature across the system.

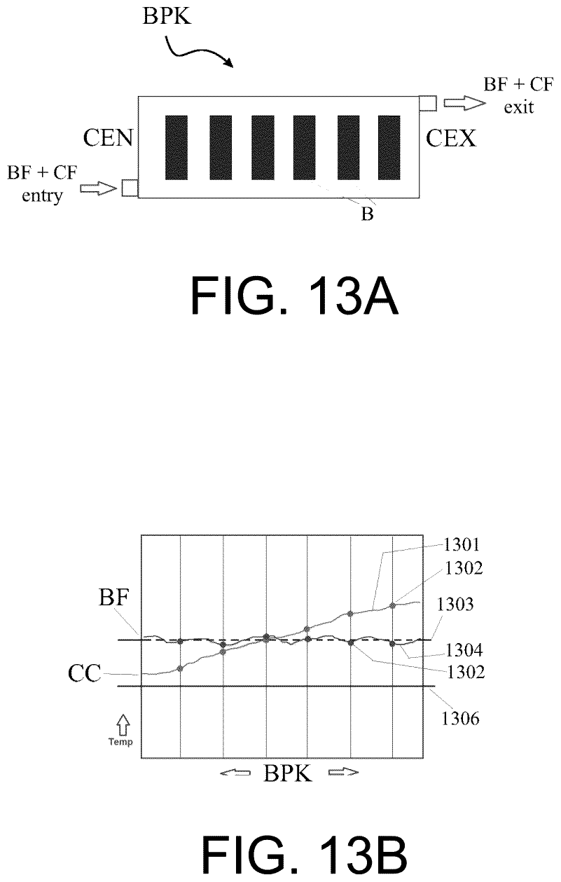

FIG. 13A illustrates a battery pack (BPK) for an electric vehicle with batteries (B).

This battery pack (BPK), an associated cooling system, has a cooling system with an inlet and an outlet.

Individual batteries (B) are arranged inside the battery pack (BPK), with passages for coolant (or cooling mechanism). Heat generated or absorbed is not uniform across all batteries (B). However, a functionally ‘optimal temperature’ across the batteries is the same, which is dependent on chemistry, operating conditions, and the like. Parameters, of battery, such as safety, charge capacity, life, endurance, and the like are based on optimal temperature characteristics. A deviation from the operating temperature, on either side, would result in reduced efficiency of some parameters. In prior art methods (regular coolant, or such types), cold coolant gets into the system, absorbs heat from the system, then exits. The coolant, as it flows from the entry to exit, absorbs heat from the system, due to which, temperature inside the system is never at one ‘optimal temperature’ range, where the temperature of the batteries is highest the close they are to the exit.

This same battery pack (BPK) was first cooled with prior art's conventional coolant (CC) entry (CEN) and coolant exit (CEX) and, then, cooled with the current invention's base fluid (BF)+carrier fluid (CF) entry and exit following the same route.

FIG. 13B illustrates a graph showing temperature across a battery pack, where ambient temperature is lower than required optimal temperatures.

It was observed that, in the current invention, which has the cooling system, of this invention, between the batteries (B), of the battery pack (BPK), temperature is the same ‘optimal temperature’ (1303) across the system/pack. For a given pressure and flow rate control, heat of evaporation is same across the system.

From the graph, a situation can be seen where ambient temperature (1306) is lower than ‘optimal temperature’. In such a case, conventional (prior art) coolant will enter at a temperature lower than ‘optimal temperature’ (1303), and exit at a higher temperature.

In the proposed system, the base fluid (BF) can be pre-heated to an optimal temperature (1303), and by controlling pressure and flow rate, the ‘optimal temperature’ (1303) can be maintained across the system, irrespective of entry temperature of base fluid. The graph shows battery temperatures (1301) of prior art's system and battery temperatures (1304) of current invention's system (1304), as compared with an ‘optimal temperature’ (1303). Reference numeral 1302 refers to individual battery temperature.

TECHNICAL ADVANTAGES: 1) High cooling capacity, for unit mass of coolant and volume of cooling system; 2) Non-localized—heat absorption occurs evenly across the system; 3) Dynamics target temperatures—Reduces thermal shocks to target, as well as easier control to ensure system operates in most efficient zones; 4) Direct heat absorption, without having to use an intermediate heat exchanger; 5) Specific target and location-based heat absorption—by control of flow-control valves, the heat absorption can be zone specific; 6) Easier heat absorbing intensity and target temperature control—by adjusting the mass of base fluid flow into secondary chamber, the pressure in secondary chamber and mass flow of carrier fluid; 7) Uniform cooling temperature across cooling system—as heat of vapourization is pressure dependent, and the vapours are carried out in dedicated secondary chamber assisted by carrier fluid, cooling system maintains same temperature across it; 8) Immediate cooling—The cooling is dependent on pressure reduction, which can be achieved in order of seconds; 9) Lower cost of infrastructure for the same cooling performance—as compared to other solutions; 10) Inherently safe, in case of leaks, ruptures, etc.

According to a non-limiting exemplary embodiment, the following cooling effect comparison can be made:
1) Prior art's cooling: Assumptions, coolant is water with specific heat capacity of approximately 4.1 KJ/(KgK), the temperature differential of coolant entering and exiting the heat exchanger on the target is 10 deg C., in which case, 1 Kg of coolant is able to absorb 41 KJ of heat.
2) Current invention's cooling: 1 Kg of water absorbs approximately 2398 KJ of heat, at 45 deg C. with pressure of 0.1 bar absolute.

Using the configuration of only the base fluid, without the carrier fluid, along with valves and a low-pressure chamber with an enclosed target, cooling of the target, can be achieved directly, without having to use a heat exchanger (which is, typically, a requirement of prior art systems). Additionally, using this system, multiple target temperatures can be achieved within the same system since a valve is configured per temperature range per pressure range.

According to a non-limiting exemplary embodiment, the system, of this invention, can achieve an adjustable target temperature and cooling intensity. Low-pressure pressure adjusts evaporating temperature, and valve/s control intensity of cooling. (in prior art cooling systems that use phase change, they use higher pressure, and the cooling is either maximum or nothing. E.g., a refrigerant is always at about minus 40 deg C., the quantity of which is allowed into a heat exchanger controlled to achieve target temperature. This cause excessive thermal shocks. Common issues are higher rate of heat exchanger failures are seen in field use). However, since this system is defined to work per pressure range/s corresponding to temperature range/s, controlled cooling can be achieved.

The TECHNICAL ADVANCEMENT of this invention lies in providing a system which uses negative pressure over atmosphere to cool a target; this system being achieved in relation to defining valves for spraying base fluid over targets to be cooled, the valves being configured per temperature range per pressure range per cooling intensity.

The TECHNICAL ADVANCEMENT of this invention lies in providing a system which moves away from evaporative cooling and introduces vacuum based cooling so that a target can be cooled, directly, as against cooling a water quantity inside a water reservoir that, in turn, acts as a coolant; this, primarily, eliminates the need for a water reservoir/coolant reservoir. Due to this configuration, there is direct cooling of the target and there is no immersion of any kind in fluid. In this invention, two fluids are used:
a) a base fluid to provide latent heat of evaporation-based cooling; and
b) a carrier fluid to assist movement of base fluid and to provide initial temperature drop.

The TECHNICAL ADVANCEMENT of this invention lies in providing a system such that cooling is achieved in two stages:
while the base fluid (BF) is sprayed (second level);
while the base fluid (BF) changes state (first level) due to change in latent heat of evaporation due to application of a vacuum.

While this detailed description has disclosed certain specific embodiments for illustrative purposes, various modifications will be apparent to those skilled in the art which do not constitute departures from the spirit and scope of the invention as defined in the following claims, and it is to be distinctly understood that the foregoing descriptive matter is to be interpreted merely as illustrative of the invention and not as a limitation.

1. A system for pressure-based cooling, the system comprising:
a primary chamber holding a base fluid in a liquid state;
a secondary chamber holding a carrier fluid, wherein the secondary chamber is configured to receive a controlled amount of the base fluid from the primary chamber, wherein the secondary chamber has a substantially lower pressure than the primary chamber such that a pressure differential cases the base fluid to change state to a vapor state while moving from the primary chamber to the secondary chamber so as to absorb heat causing cooling at a first level, wherein the carrier fluid is configured to aid movement of the base fluid from the primary chamber to the secondary chamber; and
a flow controller configured to control flow of the base fluid from the primary chamber to the secondary chamber.

2. The system as claimed in claim 1, further comprising:
at least one of a pump and a non-circulating type base fluid, wherein the base fluid in the primary chamber is configured to be circulated by the at least one of the pump and the non-circulating type base fluid.

3. The system as claimed in claim, 1 wherein the primary chamber is thermally conductive.

4. The system as claimed in claim 1, wherein the secondary chamber is lined with a fluid-absorbing, thermally-conductive material to absorb the base fluid while the base fluid evaporates.

5. The system as claimed in claim 1, wherein at least one of an outer surface of the secondary chamber and a surface of the primary chamber on a side of the secondary chamber are a target of the cooling.

6. The system as claimed in claim 1, wherein the secondary chamber is connected to a pressure drive maintaining the pressure differential between the primary chamber and the secondary chamber, and wherein the pressure drive is configured to adjust the pressure differential based on required cooling temperature and cooling intensity.

7. The system as claimed in claim 1, wherein the secondary chamber is a negative pressure chamber so as to lower a boiling point of the base fluid entering the secondary chamber.

8. The system as claimed in claim 1, further comprising:
a target being coupled to the primary chamber, wherein the base fluid is configured to absorb heat from the target from the primary chamber and the base fluid in the secondary chamber is configured to directly absorb heat of the base fluid in the primary chamber and indirectly absorb heat from the target.

9. The system as claimed in claim 1, further comprising:
a target being coupled to the secondary chamber, wherein the base fluid is configured to absorb heat directly from the target from the secondary chamber.

10. The system as claimed in claim 1, wherein the flow controller is a barrier between the primary chamber and the secondary chamber that allows a controlled amount of the base fluid into the secondary chamber.

11. The system as claimed in claim 1, wherein the flow controller is a membrane that allows the base fluid to flow through it under at least one of the pressure differential, a mechanical force, an electronic signal, and a resonant frequency.

12. The system as claimed in claim 1, wherein the flow controller includes mechanical or electromechanical micro valves that allow flow of the base fluid from the primary chamber to the secondary chamber, wherein the vales are configured to actuate under at least one of, the pressure differential between the primary chamber and the secondary chamber, a mechanical force, an electronic signal, and a resonant frequency.

13. The system as claimed in claim 1, wherein the primary chamber, the secondary chamber, and the flow controller are all thermally conductive and flexible, and wherein the flow controller includes a semi-permeable membrane separating the primary chamber from the secondary chamber and in fluid communication with the primary chamber and the secondary chamber.

14. The system as claimed in claim 1, further comprising:
a vacuum generator connected to the secondary chamber to generate a vacuum in the secondary chamber, wherein the carrier fluid is configured to carry vapor to the vacuum generator and maintain a flow velocity for cooling by vaporization of the base fluid on the flow controller.

15. The system as claimed in claim 1, wherein the flow controller includes valves configured to spray the base fluid from the primary chamber to the secondary chamber so as to cause cooling at a second level.

16. The system as claimed in claim 1, wherein the primary chamber is concentric and coaxial with the secondary chamber, wherein the flow controller includes valves on an inner circumference of the primary chamber and one or more cables passing through the secondary chamber.

17. The system as claimed in claim 1, wherein the flow controller includes one or more flow-control valves configured to control the flow of the base fluid using at least one of vacuum, temperature, flow rate, humidity, and atomization.

18. The system as claimed in claim 1, wherein the flow controller includes one or more flow-control valves configured to control the flow of the carrier fluid using at least one of vacuum, temperature, flow rate, humidity, and atomization.

19. The system as claimed in claim 1, further comprising:
inlet valves for the base fluid and the carrier fluid;
a vacuum configured to apply the pressure differential between the primary chamber and the secondary chamber; and
a controller configured to control the inlet valves, the vacuum, a temperature of the base fluid, and a temperature of the carrier fluid.

20. The system as claimed in claim 1, wherein at least one of an outer surface of the secondary chamber and a surface of the primary chamber on a side of the secondary chamber are a target for being cooled and connected to a heat exchanger.
